(19) United States
(12) Patent Application Publication
(10) Pub. No.: US 2025/0057025 A1
(43) Pub. Date: Feb. 13, 2025

(54) DISPLAY DEVICE AND METHOD FOR INSPECTING THE DISPLAY DEVICE

(71) Applicant: Samsung Display Co., Ltd., Yongin-Si (KR)

(72) Inventors: Seong Ji KO, Yongin-si (KR); Young Suk LEE, Yongin-si (KR)

(21) Appl. No.: 18/605,581

(22) Filed: Mar. 14, 2024

(30) Foreign Application Priority Data
Aug. 9, 2023 (KR) 10-2023-0104150

(51) Int. Cl. H10K 59/80; G01Q 60/24; H10K 59/40

(52) U.S. Cl. CPC H10K 59/8792; G01Q 60/24; H10K 59/40

(57) ABSTRACT

A display device includes, a substrate, a light emitting element layer on the substrate and including a plurality of light emitting elements, and a light control layer on the light emitting element layer and including a light transmitting film and a light blocking film. The light control layer further includes an inspection pattern that overlaps the light blocking film in a first direction, and the inspection pattern extends in the first direction which is the same direction as an extension direction of regions of the light blocking film.

### CROSS-REFERENCE TO RELATED APPLICATION

This application claims priority from Korean Patent Application No. 10-2023-0104150 filed on Aug. 9, 2023, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device and a method for inspecting the display device.

### Description of the Related Art

A display device may be a flat panel display device such as a liquid crystal display, a field emission display, or a light emitting display. A light emitting display device may be an organic light emitting display device, which includes an organic light emitting diode element as a light emitting element, or an inorganic light emitting diode display device, which includes an inorganic light emitting diode element such as a light emitting diode (LED) as a light emitting element.

The advance of our information-oriented society has placed more and more demands on display devices. For example, when an image is displayed on a vehicle display device at night, the image may be reflected off the windshield of the vehicle, and the reflected image may interfere with a driver's driving. Accordingly, control of the viewing angle of the image displayed on the vehicle display device may be needed to prevent such reflections. In addition, control of the viewing angle of an image displayed on the vehicle display device disposed in front of a driver may be necessary to protect privacy by preventing a passenger from viewing the image.

### SUMMARY

Aspects of the present disclosure provide a display device including an inspection pattern for measuring an etching amount and etching shape of a light transmitting layer, and a method for inspecting the display device.

Aspects of the present disclosure also provide a display device having improved reliability of a light control layer, and a method for inspecting the display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate, a light emitting element layer disposed on the substrate and including a plurality of light emitting elements, and a light control layer disposed on the light emitting element layer and including a light transmitting film and a light blocking film. The light control layer further includes an inspection pattern that overlaps the light blocking film in a first direction, and the inspection pattern extends in the first direction which is the same direction as an extension direction of regions of the light blocking film.

In an embodiment, the inspection pattern is disposed between at least two of the regions of light blocking films, the at least two regions being aligned along the first direction.

In an embodiment, regions of the light transmitting film and the regions of the light blocking film are disposed alternately in a second direction different from the first direction.

In an embodiment, the inspection pattern is disposed between regions of the light transmitting films that are adjacent in the second direction.

In an embodiment, the regions of the light transmitting films disposed on opposite sides of the inspection pattern are connected to each other by the inspection pattern, and the regions of the light transmitting films disposed on opposite sides of the inspection pattern are physically coupled with the inspection pattern to form a single component.

In an embodiment, the inspection pattern contains the same material as the light transmitting film.

In an embodiment, in a second direction different from the first direction, a width of the inspection pattern is equal to a width of each of the regions of the light blocking film.

In an embodiment, a length of the inspection pattern in the first direction is greater than a width of the inspection pattern in a second direction different from the first direction.

In an embodiment, a thickness of the inspection pattern is equal to a thickness of the light transmitting film.

In an embodiment, the substrate comprises a display area where the plurality of light emitting elements are disposed, and a non-display area disposed on at least one side of the display area, and the inspection pattern is disposed in the display area.

In an embodiment, the display area comprises an emission area configured to emit the light, and the inspection pattern does not overlap the emission area.

In an embodiment, the regions of the light blocking film comprises a plurality of light blocking films that are separate from each other in a second direction different from the first direction, the inspection pattern comprises a plurality of sub-inspection patterns, and the plurality of sub-inspection patterns each overlap, in the first direction, the plurality of regions of the light blocking film.

In an embodiment, the display device may further comprise a plurality of pixels in which the plurality of light emitting elements are respectively disposed, the inspection pattern comprises a first inspection pattern and a second inspection pattern, and the first inspection pattern and the second inspection pattern are disposed between the pixels adjacent to each other.

In an embodiment, in a second direction different from the first direction, a width the regions of the light transmitting film is greater than a width of the regions of the light blocking film.

According to an aspect of the present disclosure, a display device includes a substrate, a light emitting element layer disposed on the substrate and including a plurality of light emitting elements, and a light control layer disposed on the light emitting element layer and including a first light transmitting film region, a light blocking film region, and a second light transmitting film region. The first light transmitting film region, the light blocking film region, and the second light transmitting film region disposed alternately in a first direction. The light control layer further includes an inspection pattern disposed between the first light transmitting film region and the second light transmitting film region in the first direction, the light blocking film region includes a first light blocking film segment and a second light blocking film segment that are adjacent in a second direction different from the first direction, and the inspection pattern is disposed between the first light blocking film segment and the second light blocking film segment in the second direction.

In an embodiment, the first light blocking film segment, the second light blocking film segment, and the inspection pattern extend in the second direction.

In an embodiment, a thickness of the inspection pattern is equal to a thickness of the light blocking film.

According to an aspect of the present disclosure, there is provided a method for inspecting a display device including a substrate, a light emitting element layer disposed on the substrate and including a plurality of light emitting elements, a light transmitting film including a plurality of light transmitting film regions disposed on the light emitting element layer, and an inspection pattern disposed between the light transmitting film regions. The method includes inspecting the light transmitting film using an atomic force microscope having a tip, wherein the inspection pattern extends in a first direction which is the same direction as an extension direction of the regions of the light transmitting film, and in the inspecting of the light transmitting film, the tip moves in the first direction.

In an embodiment, a length of the inspection pattern in the first direction is greater than a width of the inspection pattern in a second direction different from the first direction.

In an embodiment, the method may further comprise a light blocking film between the regions of the light transmitting film.

According to the display device and the method for inspecting the display device according to one embodiment of the present disclosure, an inspection pattern for measuring an etching amount and etching shape of a light transmitting layer may be included.

According to the display device and the method for inspecting the display device according to one embodiment of the present disclosure, reliability of a light control layer may be improved.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings.

FIG. 1 is an exploded perspective view showing a display device according to one embodiment.

FIG. 2 is a plan view illustrating a display device according to one embodiment.

FIG. 3 is an exploded perspective view showing a display device according to another embodiment.

FIG. 4 is a schematic cross-sectional view illustrating the display device taken along line X1-X1′ of FIG. 2.

FIG. 5 is a cross-sectional view illustrating an example of a display panel according to one embodiment.

FIG. 6 is a plan view illustrating a part of a display area including an emission area in a display device according to one embodiment.

FIG. 7 is a plan view illustrating a part of a light control layer and a display area including an emission area in a display device according to one embodiment.

FIG. 8 is a cross-sectional view taken along line X2-X2′ of FIG. 7.

FIG. 9 is an enlarged view of area A of FIG. 7.

FIG. 10 is a cross-sectional view taken along line X3-X3′ of FIG. 9.

FIG. 11 is a plan view illustrating a part of a light control layer and a display area including an emission area in a display device according to another embodiment.

FIG. 12 is a plan view illustrating a part of a light control layer and a display area including an emission area in a display device according to another embodiment.

FIG. 13 is a flowchart illustrating a method for inspecting a display device according to one embodiment.

FIG. 14 is a cross-sectional view showing a structure that step S100 of FIG. 13 may form.

FIG. 15 is a cross-sectional view showing a structure that step S200 of FIG. 13 may form.

FIG. 16 is a cross-sectional view showing a structure that step S300 of FIG. 13 may form.

FIG. 17 is a perspective view showing a structure that step S400′ according to a comparative embodiment may form.

FIG. 18 is a perspective view showing a structure that step S400 of FIG. 13 may form.

FIG. 19 is a cross-sectional view showing a structure that step S400 of FIG. 13 may form.

FIG. 20 is a cross-sectional view showing a structure that step S500 of FIG. 13 may form.

### DETAILED DESCRIPTION OF THE EMBODIMENTS

Specific embodiments of the present disclosure are described more fully hereinafter with reference to the accompanying drawings. Embodiments may, however, take different forms and should not be construed as being limited to the specific embodiments set forth herein. Rather, these embodiments are provided so that this disclosure will be thorough and complete and will fully convey principles of the present disclosure to those skilled in the art.

In the following, when a layer is referred to as being “on” another layer or substrate, the layer can be directly on the other layer or substrate, or intervening layers may also be present.

The same reference numbers indicate the same or similar components throughout the specification and the drawings.

Hereinafter, embodiments of the present disclosure will be described in detail with reference to the accompanying drawings.

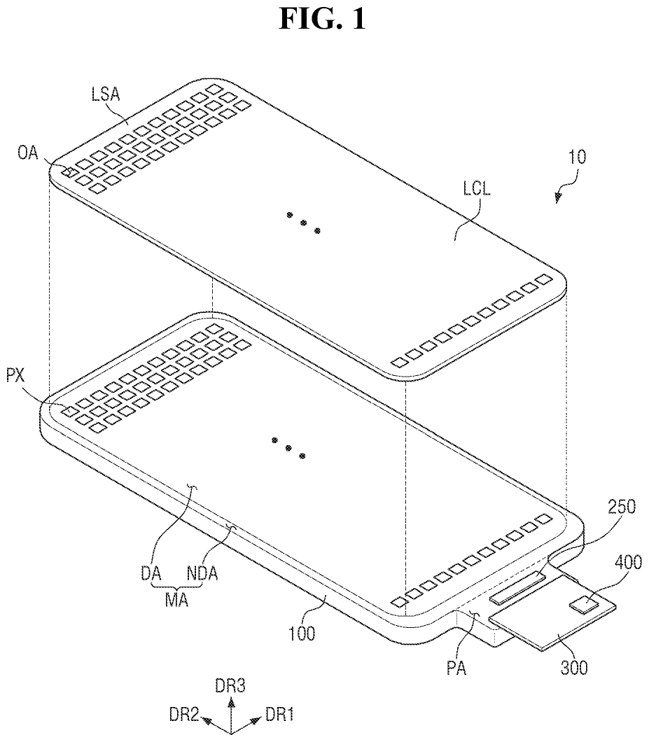

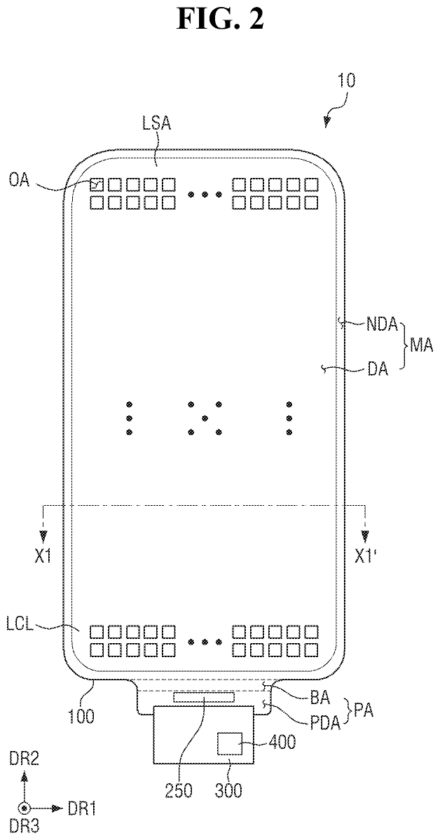

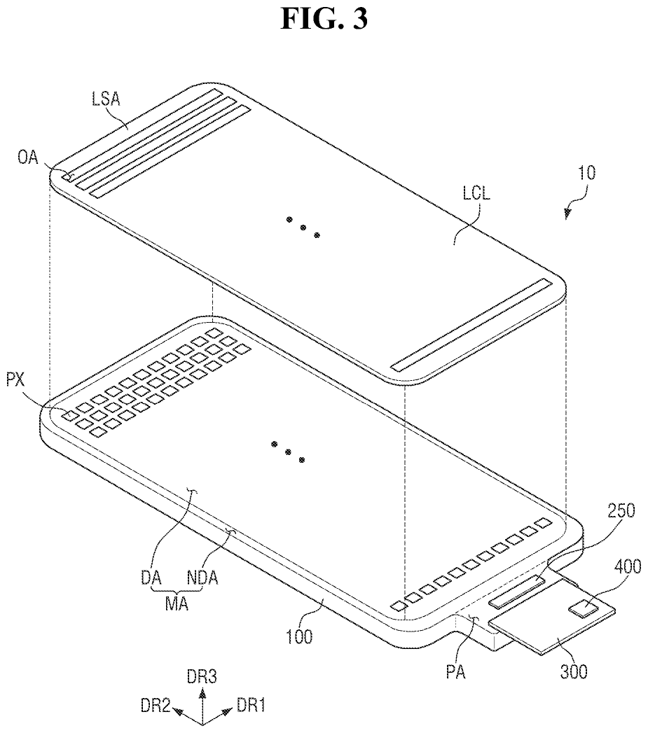

FIG. 1 is an exploded perspective view showing a display device according to one embodiment. FIG. 2 is a plan view illustrating a display device according to one embodiment. FIG. 3 is an exploded perspective view showing a display device according to another embodiment.

Referring to FIGS. 1 to 3, a display device 10 may be a device for displaying a moving image or a still image. The display device 10 may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). The display device 10 may be any one of an organic light emitting display device, a liquid crystal display device, a plasma display device, a field emission display device, an electrophoretic display device, an electrowetting display device, a quantum dot light emitting display device, a micro-LED display device, and the like. In the following description, it is assumed that the display device 10 is an organic light emitting display device, but the present disclosure is not limited thereto.

The display device 10 according to one embodiment may include a display panel 100, a display driving circuit 250, a circuit board 300, and a touch driving circuit 400.

The display panel 100 may include a plurality of pixels PX arranged in a first direction DR1 and a second direction DR2. Each of the pixels PX may have a rectangular, square, or rhombic shape in plan view. For example, as shown in the drawing, each of the pixels PX may have a square shape in plan view. However, embodiments are not limited thereto, and pixels PX may have various shapes such as the shapes of a polygon, a circle, and an ellipse in plan view.

In the illustrated figure, the first direction DR1 and the second direction DR2 cross each other in horizontal plane. For example, the first direction DR1 and the second direction DR2 may be orthogonal to each other. In addition, a third direction DR3 crosses the first direction DR1 and the second direction DR2, and may be, for example, perpendicular or orthogonal to the first direction DR1 and the second direction DR2.

The display panel 100 may include a main area MA and a protrusion area PA protruding from one side of the main area MA.

The main area MA may, in plan view, have a rectangular shape with short sides extending in the first direction DR1 and long sides extending in the second direction DR2. Each corner where a short side and a long side meet may be rounded to have a predetermined curvature or may be right-angled. The planar shape of the display device 10 is not limited to a quadrilateral shape and may be formed in another polygonal shape, a circular shape, or an elliptical shape. The main area MA may be formed flat, but is not limited thereto, and may include curved portions formed at left and right ends or edges. In this case, the curved portions may have a constant curvature or a variable curvature.

The main area MA may include a display area DA where the pixels PX may display an image and a non-display area NDA that is a peripheral area of the display area DA.

In the display area DA, not only the pixels PX, but also scan lines, data lines, and power lines connected to the pixels PX may be disposed. When the main area MA includes a curved portion, the display area DA may extend onto the curved portion. In this case, at least a portion of the image on the display panel 100 may also be seen on the curved portion.

The non-display area NDA may be defined as an area extending from the boundary of the display area DA to the edge of the display panel 100. A scan driver for applying scan signals to the scan lines and link lines connecting the data lines to the display driving circuit 250 may be disposed in the non-display area NDA.

The protrusion area PA may protrude from one side of the main area MA. For example, the protrusion area PA may protrude from the lower side of the main area MA as shown in FIG. 2. A length of the protrusion area PA in the first direction DR1 may be smaller than a length of the main area MA in the first direction DR1.

The protrusion area PA may include a bending area BA and a pad area PDA. In this case, the pad area PDA may be disposed on one side of the bending area BA, and the main area MA may be disposed on the other side of the bending area BA. For example, the pad area PDA may be disposed below the bending area BA, and the main area MA may be disposed above the bending area BA.

The display panel 100 may be flexible such that the display panel 100 can be curved, bent, folded, or rolled. Accordingly, the display panel 100 may be bent in the thickness direction, that is, in the third direction DR3 in the bending area BA. In this case, one surface of the pad area PDA of the display panel 100 faces upward before the display panel 100 is bent, but after the display panel 100 is bent, that surface of the pad area PDA of the display panel 100 faces downward. Accordingly, since the pad area PDA may be disposed below the main area MA after bending, the pad area PDA may overlap the main area MA.

Pads electrically connected to the display driving circuit 250 and the circuit board 300 may be disposed in the pad area PDA of the display panel 100.

The display driving circuit 250 outputs signals and voltages for driving the display panel 100. For example, the display driving circuit 250 may supply data voltages to data lines. Further, the display driving circuit 250 may supply a power voltage to the power line and may supply scan control signals to the scan driver. The display driving circuit 250 may be formed as an integrated circuit (IC) and mounted on the display panel 100 in the pad area PDA. A chip on glass (COG) method, a chip on plastic (COP) method, or an ultrasonic bonding method may mount the display driving circuit 250 on the display panel 100, but the present disclosure is not limited thereto. For example, the display driving circuit 250 may be mounted on the circuit board 300.

The pads may include display pads electrically connected to the display driving circuit 250 and touch pads electrically connected to touch lines.

The circuit board 300 may be attached onto the pads using an anisotropic conductive film. Accordingly, lead lines of the circuit board 300 may be electrically connected to the pads. The circuit board 300 may be a flexible printed circuit board, a printed circuit board, or a flexible film such as a chip on film.

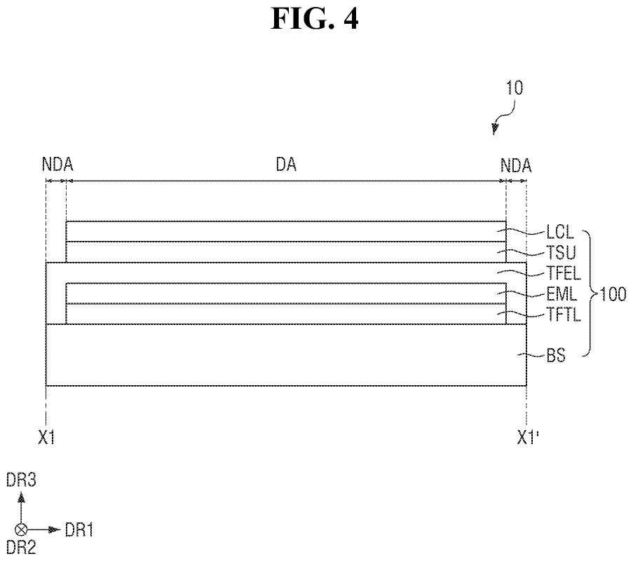

The touch driving circuit 400 may be connected to touch electrodes of a touch sensor layer TSU (see FIG. 4) of the display panel 100. The touch driving circuit 400 applies driving signals to the touch electrodes of the touch sensor layer TSU (see FIG. 4) and measures capacitance values of the touch electrodes. The driving signal may be a signal having a plurality of driving pulses. The touch driving circuit 400 may determine whether or not touch is inputted based on capacitance values associated with the touch electrodes and may calculate touch coordinates at which a touch is input.

The touch driving circuit 400 may be disposed on the circuit board 300. The touch driving circuit 400 may be formed as an integrated circuit (IC) and mounted on the circuit board 300.

In the display device 10 according to the present embodiment, the display panel 100 may further include a light control layer LCL.

The light control layer LCL may be directly disposed on the main area MA of the display panel 100. For example, the light control layer LCL may be embedded in the display panel 100 and directly disposed on the main area MA of the display panel 100. By embedding the light control layer LCL in the display panel 100, the thickness and manufacturing cost of the display device 10 may be reduced compared to a case where a separate light control film is attached.

In some embodiments, the light control layer LCL may be disposed on the display area DA of the main area MA. The light control layer LCL may adjust a viewing angle of light emitted from the display panel 100.

In some embodiments, the light control layer LCL may be larger than that of the display area DA in plan view. In this case, the light control layer LCL may overlap both the display area DA and the non-display area NDA.

The light control layer LCL may include transmission areas OA arranged in the first and second directions DR1 and DR2, and a non-transmission area LSA surrounding the transmission areas OA.

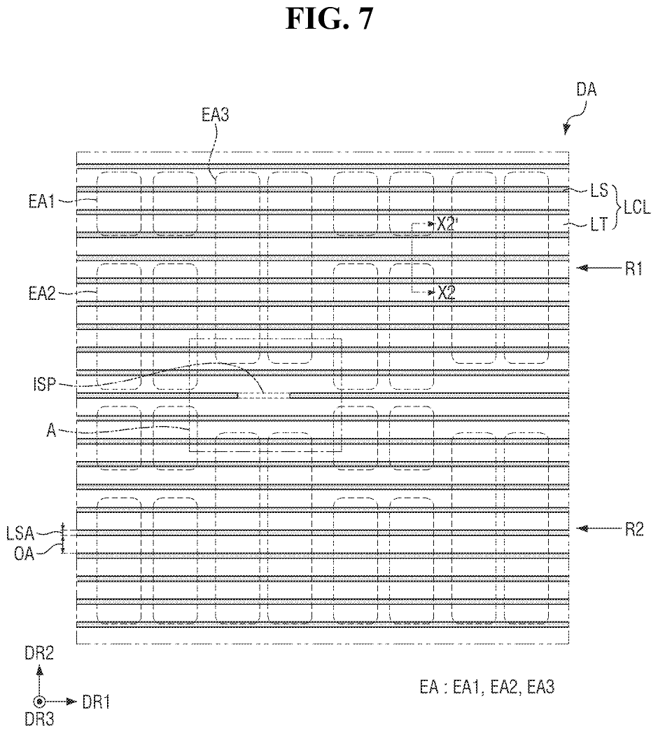

The transmission areas OA may be areas in which a light blocking film LS (see FIG. 7) is not disposed. The transmission areas OA are areas that transmit light.

Each of the transmission areas OA may have a quadrilateral shape in plan view, as illustrated in FIGS. 1 and 2, but the shape is not limited thereto. Each of the transmission areas OA may have a circular shape, an elliptical shape, or a polygonal shape in plan view.

In another embodiment, the transmission areas OA may have a shape with a greater length extending in the first direction DR1 or the second direction DR2. For example, as shown in FIG. 3, each of the transmission areas OA may extend primarily in the first direction DR1, and the transmission areas OA may be arranged along the second direction DR2. As another example, each of the transmission areas OA may extend primarily in the second direction DR2, and the transmission areas OA may be arranged along the first direction DR1.

When the transmission areas OA are arranged along the first and second directions DR1 and DR2 as shown in FIG. 1, the viewing angle may be controlled in both the first and second directions DR1 and DR2. When the transmission areas OA are arranged along the first direction DR1 or the second direction DR2 as shown in FIG. 3, the viewing angle may be controlled in the first direction DR1 or the second direction DR2. That is, the arrangement and shape of the transmission areas OA may be variously modified depending on the required viewing angle control direction.

The non-transmission area LSA may be a remaining area of the light control layer LCL excluding the transmission areas OA. The non-transmission area LSA may be an area in which the light blocking film LS (see FIG. 7) is disposed.

In the drawing, the non-transmission area LSA is shown as surrounding the transmission areas OA, but the non-transmission area LSA is not limited thereto. In some embodiments, the non-transmission area LSA may include regions that extend in the same direction as regions of the transmission area OA and that may be alternately disposed or interleaved with the regions of the transmission area OA. For example, as shown in FIG. 3, when the transmission area OA extends in the first direction DR1, the non-transmission area LSA may include regions that primarily extend in the first direction DR1, and the regions of the non-transmission area LSA may be arranged in the second direction and disposed between adjacent regions of the transmission area OA.

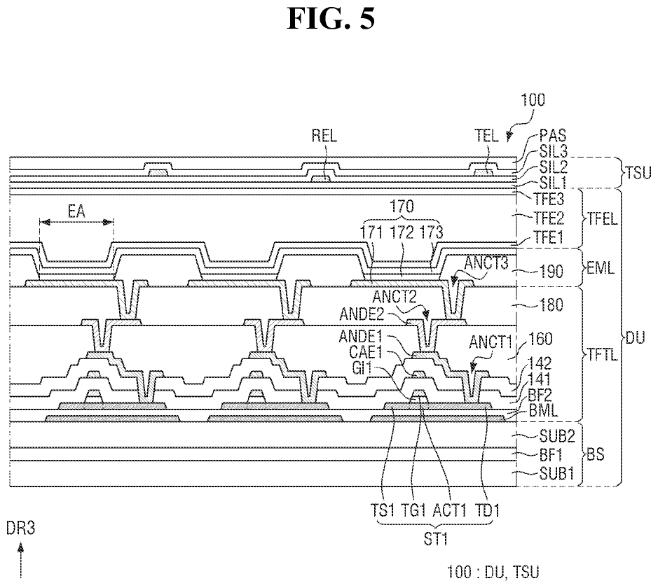

The light control layer LCL may include the light blocking film LS (see FIG. 7) that blocks light emitted from a light emitting layer 172 (see FIG. 5) of the display panel 100, and a light transmitting film LT (see FIG. 7) that transmits light. A detailed structure of the light control layer LCL will be described later with reference to FIG. 7 and the like.

FIG. 4 is a schematic cross-sectional view illustrating the display device 10 taken along line X1-X1′ of FIG. 2.

Referring to FIG. 4, the display device 10 may include the display panel 100 in which the light control layer LCL is embedded. The display panel 100 may include a base member BS, a thin film transistor layer TFTL, a light emitting element layer EML, a thin film encapsulation layer TFEL, the touch sensor layer TSU, and the light control layer LCL.

The base member BS may include a substrate. The substrate may be formed of an insulating material such as glass, quartz, or a polymer material or resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate may include a metal material.

The substrate may be a rigid substrate or a flexible substrate, which can be bent, folded, or rolled. When the substrate is a flexible substrate, the substrate may be formed of polyimide (PI) but is not limited thereto.

The thin film transistor layer TFTL may be disposed on the base member BS. In the thin film transistor layer TFTL, scan lines, data lines, power lines, scan control lines, and routing lines connecting pads to data lines, as well as thin film transistors of each of the pixels, may be formed. Each of the thin film transistors may include a gate electrode, a semiconductor layer, a source electrode, and a drain electrode.

The thin film transistor layer TFTL may be disposed in the display area DA and the non-display area NDA. Specifically, thin film transistors, scan lines, data lines, and power lines of each of the pixels of the thin film transistor layer TFTL may be disposed in the display area DA. The scan control lines and the link lines of the thin film transistor layer TFTL may be disposed in the non-display area NDA.

A light emitting element layer EML may be disposed on the thin film transistor layer TFTL. The light emitting element layer EML may include light emitting elements of the pixels including a first electrode, a light emitting layer, and a second electrode, and a pixel defining layer defining areas of the light emitting elements. The light emitting layer may be an organic light emitting layer containing an organic material. In this case, the light emitting layer may include a hole transporting layer, an organic light emitting layer, and an electron transporting layer. When a predetermined voltage is applied through the thin film transistor of the thin film transistor layer TFTL to the first electrode and a cathode voltage is applied to the second electrode, holes and electrons are transferred to the organic light emitting layer through a hole transporting layer and an electron transporting layer, respectively and are combined with each other to emit light in the organic light emitting layer. The pixels of the light emitting element layer EML may be disposed in the display area DA.

The thin film encapsulation layer TFEL may be disposed on the light emitting element layer EML. The thin film encapsulation layer TFEL may serve to prevent oxygen or moisture from permeating into the light emitting element layer EML. To this end, the thin film encapsulation layer TFEL may include at least one inorganic layer. The inorganic layer may be a silicon nitride layer, a silicon oxynitride layer, a silicon oxide layer, a titanium oxide layer, or an aluminum oxide layer, but the inorganic layer is not limited thereto. In addition, the thin film encapsulation layer TFEL may serve to protect the light emitting element layer EML from foreign substances such as dust. To this end, the thin film encapsulation layer TFEL may include at least one organic layer. The organic layer may include acryl resin, epoxy resin, phenolic resin, polyamide resin, or polyimide resin, but the organic layer is not limited thereto.

The thin film encapsulation layer TFEL may be disposed in both the display area DA and the non-display area NDA. Specifically, the thin film encapsulation layer TFEL may cover the thin film transistor layer TFT and the light emitting element layer EML in the display area DA and the non-display area NDA and may cover the thin film transistor layer TFT in the non-display area NDA where the light emitting element layer EML may not be disposed.

The touch sensor layer TSU may be disposed on the thin film encapsulation layer TFEL. The touch sensor layer TSU may be directly disposed on the thin film encapsulation layer TFEL to reduce the thickness of the display device 10 compared to a case where a separate touch panel including the touch sensor layer TSU is attached on the thin film encapsulation layer TFEL.

The touch sensor layer TSU may include touch electrodes for sensing a user's touch in a capacitive manner and the touch lines connecting the pads to the touch electrodes. For example, the touch sensor layer TSU may sense a user's touch using a self-capacitance method or a mutual capacitance method.

The touch electrodes of the touch sensor layer TSU may be disposed in a touch sensor area overlapping the display area DA. The touch lines of the touch sensor layer TSU may be disposed in a touch peripheral area overlapping the non-display area NDA.

The light control layer LCL may be disposed on the touch sensor layer TSU. The light control layer LCL may overlap the display area DA. The light control layer LCL may serve to absorb or block light that travels out of certain angles with respect to the third direction DR3 among light emitted from the light emitting element layer EML. That is, the light control layer LCL may control the viewing angle for an image on the display panel 100.

Although not shown in the drawing, the display device 10 may further include a cover window. The cover window may be additionally disposed on the light control layer LCL, and in this case, the light control layer LCL and the cover window may be attached by a transparent adhesive member such as an optically clear adhesive (OCA) film.

FIG. 5 is a cross-sectional view illustrating an example of a display panel 100 according to one embodiment.

Referring to FIG. 5, the display panel 100 may include a display layer DU and the touch sensor layer TSU. The display layer DU may include the base member BS, the thin film transistor layer TFTL, the light emitting element layer EML, and the thin film encapsulation layer TFEL.

The base member BS may include a first substrate SUB1, a first buffer layer BF1 disposed on the first substrate SUB1, and a second substrate SUB2 disposed on the first buffer layer BF1.

The first substrate SUB1 and the second substrate SUB2 may be made of an insulating material such as glass, quartz, polymer resin or the like. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate SUB1 or SUB2 may include a metal material.

The first substrate SUB1 and the second substrate SUB2 may be flexible substrates that can be bent, folded, or rolled or rigid substrates. When the substrate SUB1 or SUB2 is a flexible substrate, the substrate SUB1 or SUB2 may be formed of polyimide (PI), but embodiments are not limited thereto.

The first buffer layer BF1 is a layer for protecting a first thin film transistor ST1 and a light emitting layer 172 from moisture permeating through the first substrate SUB1 and the second substrate SUB2, which may be susceptible to moisture permeation. The first buffer layer BF1 may be formed of a stack of inorganic layers. For example, the first buffer layer BF1 may be formed of multiple layers in which one or more inorganic layers of a silicon nitride layer, a silicon oxynitride layer, a silicon oxide layer, a titanium oxide layer and an aluminum oxide layer are alternately stacked.

The thin film transistor layer TFTL may include a lower metal layer BML, a second buffer layer BF2, a first active layer ACT1, a first gate insulating layer GI1, a first interlayer insulating layer 141, a first capacitor electrode CAE1, a second interlayer insulating layer 142, a first anode connection electrode ANDE1, a first organic layer 160, a second anode connection electrode ANDE2, and a second organic layer 180.

The lower metal layer BML may be disposed on the second substrate SUB2. The lower metal layer BML may overlap in the third direction DR3 a region of the first active layer ACT1 in the first thin film transistor ST1 to prevent a leakage current from being generated when light is incident on the first active layer ACT1 of the first thin film transistor ST1. The lower metal layer BML may be formed as a single layer or multiple layers made of any of molybdenum (Mo), aluminum (Al), chromium (Cr), gold (Au), titanium (Ti), nickel (Ni), neodymium (Nd) and copper (Cu) or an alloy thereof. The lower metal layer BML may be omitted in some embodiments.

The second buffer layer BF2 may be disposed on the lower metal layer BML. The second buffer layer BF2 is a layer for protecting a first thin film transistor ST1 and a light emitting layer 172 from moisture permeating through the first substrate SUB1 and the second substrate SUB2, which may be susceptible to moisture permeation. The second buffer layer BF2 may be formed of a stack of inorganic layers. For example, the second buffer layer BF2 may be formed of multiple layers in which one or more inorganic layers of a silicon nitride layer, a silicon oxynitride layer, a silicon oxide layer, a titanium oxide layer and an aluminum oxide layer are alternately stacked.

The first active layer ACT1 may be disposed on the second buffer layer BF2. The first active layer ACT1 may include polycrystalline silicon, monocrystalline silicon, low-temperature polycrystalline silicon, amorphous silicon, or an oxide semiconductor. The region of the first active layer ACT1 in the first thin film transistor ST1 includes areas that are not covered or overlapped by a first gate insulating layer GI1, and these areas may be doped with impurities or ions, and thus may have conductivity. Accordingly, a first source electrode TS1 and a first drain electrode TD1 of the first active layer ACT1 of the first thin film transistor ST1 may be formed.

A first gate insulating layer GI1 may be disposed on the first active layer ACT1 of the first thin film transistor ST1. Although FIG. 5 illustrates that the first gate insulating layer GI1 is disposed between the first active layer ACT1 and a first gate electrode TG1 of the first thin film transistor ST1, but embodiments are not limited thereto. The first gate insulating layer GI1 may be disposed between a first interlayer insulating layer 141 and the first active layer ACT1 and between the first interlayer insulating layer 141 and the second buffer layer BF2. The first gate insulating layer GI1 may be formed of an inorganic layer, for example, a silicon nitride layer, a silicon oxynitride layer, a silicon oxide layer, a titanium oxide layer, or an aluminum oxide layer.

The first gate electrode TG1 of the first thin film transistor ST1 may be disposed on the first gate insulating layer GI1. The first gate electrode TG1 of the first thin film transistor ST1 may overlap the first active layer ACT1 in the third direction DR3. The first gate electrode TG1 of the first thin film transistor ST1 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The first interlayer insulating layer 141 may be disposed on the first gate electrode TG1 of the first thin film transistor ST1. The first interlayer insulating layer 141 may be formed of an inorganic layer, for example, a silicon nitride layer, a silicon oxynitride layer, a silicon oxide layer, a titanium oxide layer, or an aluminum oxide layer. The first interlayer insulating layer 141 may include a plurality of inorganic layers.

The first capacitor electrode CAE1 may be disposed on the first interlayer insulating layer 141. The first capacitor electrode CAE1 may overlap the first gate electrode TG1 of the first thin film transistor ST1 in the third direction DR3. The first interlayer insulating layer 141 may have a predetermined dielectric constant, and the first capacitor electrode CAE1, the first gate electrode TG1, and the first interlayer insulating layer 141 disposed therebetween may form a capacitor. The first capacitor electrode CAE1 may be formed as a single layer or multiple layers made of any of molybdenum (Mo), aluminum (Al), chromium (Cr), gold (Au), titanium (Ti), nickel (Ni), neodymium (Nd) and copper (Cu) or an alloy thereof.

The second interlayer insulating layer 142 may be disposed on the first capacitor electrode CAE1. The second interlayer insulating layer 142 may be formed of an inorganic layer, for example, a silicon nitride layer, a silicon oxynitride layer, a silicon oxide layer, a titanium oxide layer, or an aluminum oxide layer. The second interlayer insulating layer 142 may include a plurality of inorganic layers.

The first anode connection electrode ANDE1 may be disposed on the second interlayer insulating layer 142. The first anode connection electrode ANDE1 may penetrate through the first interlayer insulating layer 141 and the second interlayer insulating layer 142 to be connected to the first drain electrode TD1 of the first thin film transistor ST1 via a first anode contact hole ANCT1 overlies the first drain electrode TD1 of the first thin film transistor ST1. The first anode connection electrode ANDE1 may be formed as a single layer or multiple layers made of any of molybdenum (Mo), aluminum (Al), chromium (Cr), gold (Au), titanium (Ti), nickel (Ni), neodymium (Nd) and copper (Cu), or an alloy thereof.

The first organic layer 160 for planarization may be disposed on the first anode connection electrode ANDE1. The first organic layer 160 may be formed of an organic material such as acryl resin, epoxy resin, phenolic resin, polyamide resin, polyimide resin and the like.

The second anode connection electrode ANDE2 may be disposed on the first organic layer 160. The second anode connection electrode ANDE2 may be connected to the first anode connection electrode ANDE1 via the second anode contact hole ANCT2 penetrating through the first organic layer 160 to the first anode connection electrode ANDE1. The second anode connection electrode ANDE2 may be formed as a single layer or multiple layers made of any of molybdenum (Mo), aluminum (Al), chromium (Cr), gold (Au), titanium (Ti), nickel (Ni), neodymium (Nd) and copper (Cu), or an alloy thereof.

A second organic layer 180 may be disposed on the second anode connection electrode ANDE2. The second organic layer 180 may be formed of an organic material such as acryl resin, epoxy resin, phenolic resin, polyamide resin, polyimide resin and the like.

Although FIG. 5 illustrates that the first thin film transistor ST1 is configured to be of a top gate type in which the first gate electrode TG1 is located on top of the first active layer ACT1, the present disclosure is not limited thereto. The first thin film transistor ST1 may be configured to be of a bottom gate type in which the first gate electrode TG1 is located under the first active layer ACT1, or a double gate type in which the first gate electrode TG1 is located on and under the first active layer ACT1.

The light emitting element layer EML may be disposed on the second organic layer 180. The light emitting element layer EML may include light emitting elements 170 and a bank 190. Each of the light emitting elements 170 may include a first light emitter electrode 171, the light emitting layer 172, and a second light emitter electrode 173.

The first light emitter electrode 171 may be formed on the second organic layer 180. The first light emitter electrode 171 may penetrate through the second organic layer 180 to be connected to the second anode connection electrode ANDE2 via a third anode contact hole ANCT3 that overlaps the second anode connection electrode ANDE2.

In a top emission structure in which light is emitted toward the second light emitter electrode 173, the first light emitter electrode 171 may be formed of a metal material having high reflectivity. For example, the light emitter electrode 171 may have a stacked structure (Ti/Al/Ti) of aluminum and titanium, a stacked structure (ITO/AI/ITO) of aluminum and ITO, an APC alloy, and a stacked structure (ITO/APC/ITO) including an APC alloy and ITO. The APC alloy may be an alloy of silver (Ag), palladium (Pd) and copper (Cu).

The bank 190 may be on the second organic layer 180 and may have an opening overlapping the first light emitter electrode 171, thereby defining an emission area EA. The bank 190 may be formed to cover the edge of the first light emitter electrode 171. The bank 190 may be formed of an organic material such as acryl resin, epoxy resin, phenolic resin, polyamide resin, polyimide resin and the like.

The emission area EA represents an area in which the first light emitter electrode 171, the light emitting layer 172, and the second light emitter electrode 173 are sequentially stacked, and holes from the first light emitter electrode 171 and electrons from the second light emitter electrode 173 are combined with each other in the light emitting layer 172 to emit light.

The light emitting layer 172 may be formed on the first light emitter electrode 171 and the bank 190. The light emitting layer 172 may include an organic material to emit light having a predetermined color. For example, the light emitting layer 172 may include a hole transporting layer, an organic material layer, and an electron transporting layer.

The second light emitter electrode 173 may be disposed on the light emitting layer 172. The second light emitter electrode 173 may be formed to cover the light emitting layer 172. The second light emitter electrode 173 may be a common layer formed in common for all the emission areas EA. Although not shown, in some embodiments, a capping layer may be formed on the second light emitter electrode 173.

In the top emission structure, the second light emitter electrode 173 may be formed of transparent conductive oxide (TCO) such as indium tin oxide (ITO) and indium zinc oxide (IZO) capable of transmitting light or a semi-transmissive conductive material such as magnesium (Mg), silver (Ag), or an alloy of magnesium (Mg) and silver (Ag). When the second light emitter electrode 173 is formed of a semi-transmissive conductive material, the light emission efficiency can be increased due to a micro-cavity effect.

The thin film encapsulation layer TFEL may be disposed on the second light emitter electrode 173. The thin film encapsulation layer TFEL may include at least one inorganic layer to prevent oxygen or moisture from permeating into the light emitting element layer EML. In addition, the thin film encapsulation layer TFEL may include at least one organic layer to protect the light emitting element layer EML from foreign substances such as dust. For example, the thin film encapsulation layer TFEL may include a first encapsulation film TFE1, a second encapsulation film TFE2, and a third encapsulation film TFE3.

The first encapsulation film TFE1 (e.g., a first inorganic encapsulation film) may be disposed on the second light emitter electrode 173. The first encapsulation film TFE1 may be an inorganic layer including a single layer or multiple layers. The first encapsulation film TFE1 may be formed as a single layer or a multilayer in which one or more inorganic layers of a silicon nitride layer, a silicon oxynitride layer, a silicon oxide layer, a titanium oxide layer and an aluminum oxide layer are alternately stacked.

The second encapsulation film TFE2 (e.g., a first organic encapsulation film) may be disposed on the first encapsulation film TFE1. The second encapsulation film TFE2 may be an organic layer including a single layer or multiple layers. The second encapsulation film TFE2 may include a polymer-based material. Polymer-based materials may include polyethylene terephthalate, polyethylene naphthalate, polycarbonate, polyimide, polyethylene sulfonate, polyoxymethylene, polyarylate, hexamethyldisiloxane, and acrylic resins (e.g., polymethyl methacrylate, polyacrylic acid, or the like), or any combination thereof.

The third encapsulation film TFE3 (e.g., a second inorganic encapsulation film) may be disposed on the second encapsulation film TFE2. The third encapsulation film TFE3 may be an inorganic layer including a single layer or multiple layers. The third encapsulation film TFE3 may include the same material as the first encapsulation film TFE1. For example, the third encapsulation film TFE3 may be formed as a single layer or a multilayer in which one or more inorganic layers such as a silicon nitride layer, a silicon oxynitride layer, a silicon oxide layer, a titanium oxide layer and an aluminum oxide layer are stacked.

The touch sensor layer TSU may be disposed on the thin film encapsulation layer TFEL. The touch sensor layer TSU may include a plurality of touch electrodes for capacitive sensing a user's touch and the touch lines connecting the plurality of touch electrodes to a touch driver. For example, a mutual capacitance method or a self-capacitance method employing the touch sensor layer TSU may be used to sense the user's touch.

In another embodiment, the touch sensor layer TSU may be disposed on a separate substrate disposed on the display layer DU. In this case, the substrate supporting the touch sensor layer TSU may be an encapsulation member encapsulating the display layer DU.

The plurality of touch electrodes of the touch sensor layer TSU may be disposed in a touch sensor area overlapping the display area. The touch lines of the touch sensor layer TSU may be disposed in the touch peripheral area overlapping the non-display area.

The touch sensor layer TSU may include a first touch insulating layer SIL1, a first touch electrode REL, a second touch insulating layer SIL2, a second touch electrode TEL, and a third touch insulating layer SIL3.

The first touch insulating layer SIL1 may be disposed on the thin film encapsulation layer TFEL. The first touch insulating layer SIL1 may have insulating and optical functions. The first touch insulating layer SIL1 may include at least one inorganic layer. For example, the first touch insulating layer SIL1 may be an inorganic layer containing at least one of a silicon nitride layer, a silicon oxynitride layer, a silicon oxide layer, a titanium oxide layer, or an aluminum oxide layer. Optionally, the first touch insulating layer SIL1 may be omitted.

The first touch electrode REL may be disposed on the first touch insulating layer SIL1. The first touch electrode REL may not overlap the light emitting element 170. The first touch electrode REL may be formed as a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/AI/ITO) of aluminum and ITO, an Ag—Pd—Cu (APC) alloy, or a stacked structure (ITO/APC/ITO) of APC alloy and ITO.

The second touch insulating layer SIL2 may cover the first touch electrode REL and the first touch insulating layer SIL1. The second touch insulating layer SIL2 may have insulating and optical functions. For example, the second touch insulating layer SIL2 may be made of the material exemplified in association with the first touch insulating layer SIL1.

The second touch electrode TEL may be disposed on the second touch insulating layer SIL2. The second touch electrode TEL may not overlap the light emitting element 170. The second touch electrode TEL may be formed as a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/AI/ITO) of aluminum and ITO, an Ag—Pd—Cu (APC) alloy, or a stacked structure (ITO/APC/ITO) of APC alloy and ITO.

The third touch insulating layer SIL3 may cover the second touch electrode TEL and the second touch insulating layer SIL2. The third touch insulating layer SIL3 may have insulating and optical functions. The third touch insulating layer SIL3 may be made of the material exemplified in association with the second touch insulating layer SIL2.

In some embodiments, the first touch insulating layer SIL1, the second touch insulating layer SIL2, and the third touch insulating layer SIL3 may be organic layers. Each of the first touch insulating layer SIL1, the second touch insulating layer SIL2, and the third touch insulating layer SIL3 may be an organic layer such as acryl resin, epoxy resin, phenolic resin, polyamide resin, polyimide resin, or the like.

The touch sensor layer TSU may further include a planarization layer PAS for planarization. The planarization layer PAS may be formed of an organic material such as acryl resin, epoxy resin, phenolic resin, polyamide resin, polyimide resin and the like.

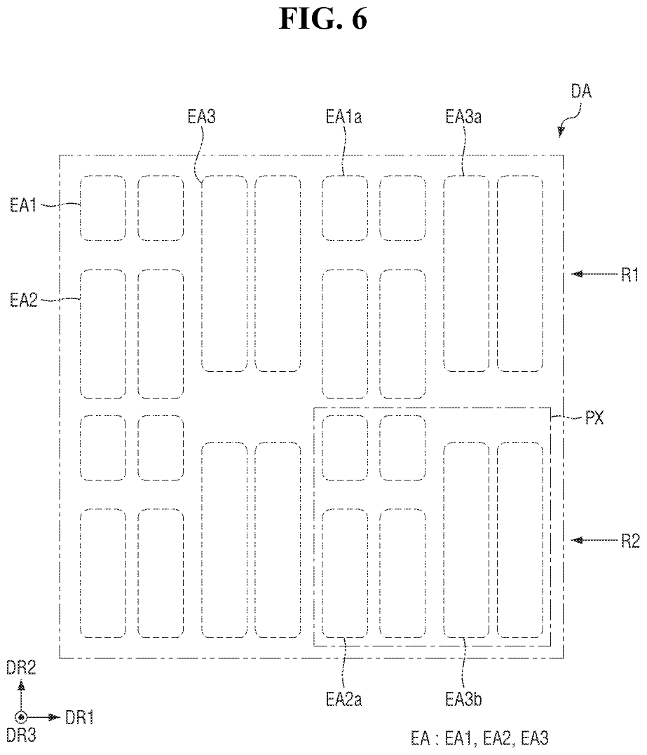

FIG. 6 is a plan view illustrating a part of a display area including an emission area in a display device according to one embodiment.

Referring to FIG. 6 in addition to FIG. 5, the display area DA of the display device 10 may include a plurality of emission areas EA. Each emission area EA may be an area through which light generated by a light emitting element may be emitted from the light emitting element layer EML.

The plurality of emission areas EA may be defined by the bank 190. For example, the plurality of emission areas EA may be areas overlapping the light emitting layer 172 disposed in openings of the bank 190. Each of the emission areas EA may be an area in which the first light emitter electrode 171, the light emitting layer 172, and the second light emitter electrode 173 are sequentially stacked while overlapping each other.

In some embodiments, the plurality of emission areas EA may include a first emission area EA1, a second emission area EA2, and a third emission area EA3. Although three types of emission areas EA are shown to be included in the display area DA in the drawing, the present disclosure is not limited thereto.

The first emission area EA1 may emit light of a first color, the second emission area EA2 may emit light of a second color, and the third emission area EA3 may emit light of a third color. The light of the first color may be light in a red wavelength band, the light of the second color may be light in a green wavelength band, and the light of the third color may be light in a blue wavelength band. The red wavelength band may be a wavelength band from about 600 nm to 750 nm, the green wavelength band may be a wavelength band from about 480 nm to 560 nm, and the blue wavelength band may be a wavelength band from about 370 nm to 460 nm, but the present disclosure is not limited thereto.

Each of the first to third emission areas EA1, EA2, and EA3 may have a rectangular, square, or rhombic shape in plan view. For example, as shown in FIG. 6, each of the first to third emission areas EA1, EA2, and EA3 may have a rectangular shape with rounded corners, but embodiments are not limited thereto.

In some embodiments, the first emission area EA1 and the second emission area EA2 may be alternately arranged together in columns extending in the second direction DR2. The third emission area EA3 may be in columns that extend in the second direction and are arranged along the first direction between the columns the first emission area EA1 and the second emission area EA2. The second emission area EA2 may overlap the first emission area EA1 in the second direction DR2, and the third emission area EA3 may overlap the first emission area EA1 and the second emission area EA2 in the first direction DR1.

The area of the third emission area EA3 may be larger than the areas of the first emission area EA1 and the second emission area EA2, and the area of the second emission area EA2 may be larger than the area of the first emission area EA1. However, the present disclosure is not limited thereto, and the first to third emission areas EA1, EA2, and EA3 may all have the same area.

Two of each of the first to third emission areas EA1, EA2, and EA3 may be included in one pixel PX. For example, two first emission areas EA1 may be disposed side by side in the first direction DR1 in one pixel PX, two second emission areas EA2 may be disposed side by side in the first direction DR1 in one pixel PX, and two third emission areas EA3 may be disposed side by side in the first direction DR1 in one pixel PX. However, the present disclosure is not limited thereto, and the number of the first to third emission areas EA1, EA2, and EA3 included in one pixel PX may vary.

In some embodiments, one end EA3a of the third emission area EA3 in the second direction DR2 included in a pixel PX disposed in a first row R1 may be disposed adjacent to one end EA1a of the first emission area EA1 in the second direction DR2 included in the pixel PX disposed in the first row R1. The other end EA3b of the third emission area EA3 in the second direction DR2 included in a pixel PX disposed in a second row R2 may be disposed adjacent to the other end EA2a of the second emission area EA2 in the second direction DR2 included in the pixel PX disposed in the second row R2. Accordingly, a distance in the second direction DR2 between the third emission area EA3 included in the pixel PX disposed in the first row R1 and the third emission area EA3 included in the pixel PX disposed in the second row R2 may be relatively large.

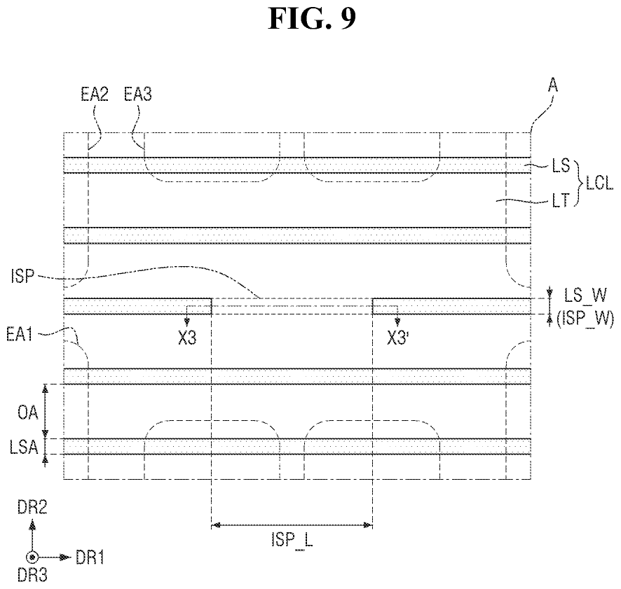

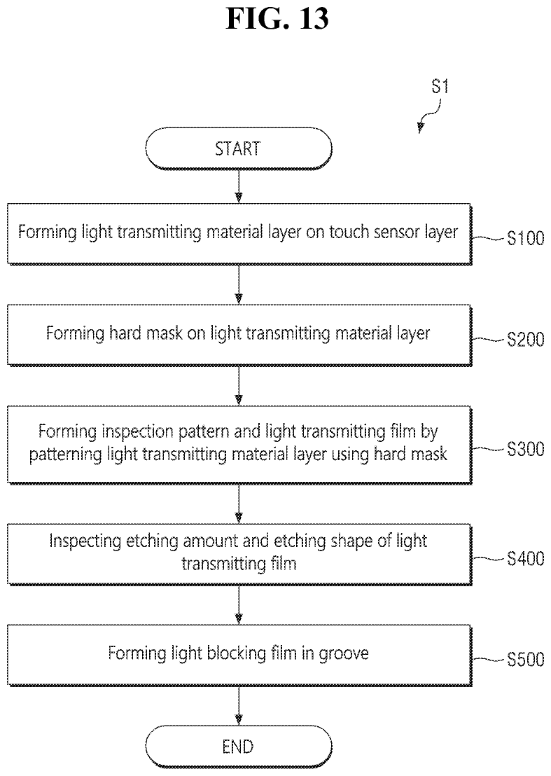

In the display device 10 according to the present embodiment, an inspection pattern ISP (see FIG. 7) to be described later may be disposed in a space formed between the third emission areas EA3 in the first row R1 and the third emission areas EA3 in the second row R2. The inspection pattern ISP (see FIG. 7) may be used to inspect the etching amount and etching shape of the light transmitting film LT (see FIG. 7) according to a display device inspection method S1 (see FIG. 13) to be described later. The inspection pattern ISP will be described further below with reference to FIGS. 7 and 9.

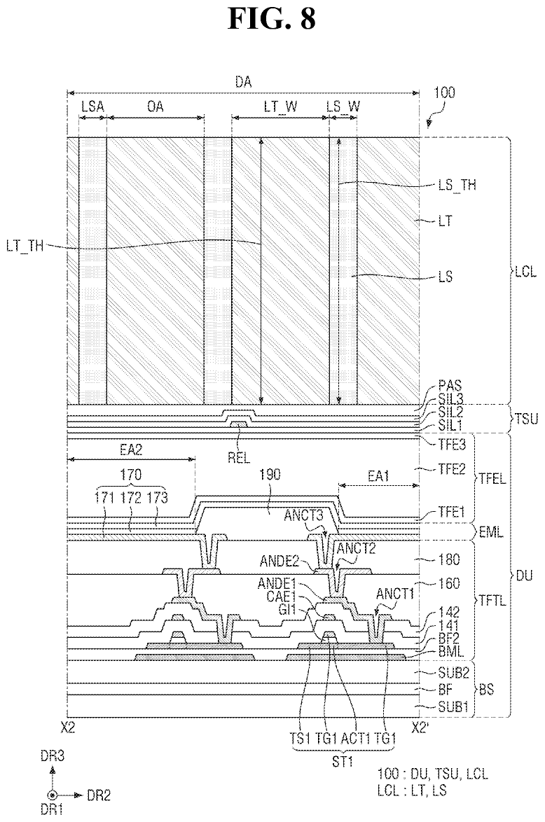

FIG. 7 is a plan view illustrating a part of a light control layer and a display area including an emission area in a display device according to one embodiment. FIG. 8 is a cross-sectional view taken along line X2-X2′ of FIG. 7.

Referring to FIGS. 7 and 8 in addition to FIGS. 1 to 3, in the display device 10 according to the present embodiment, similarly to the display device according to the embodiment of FIG. 3, the transmission area OA and the non-transmission area LSA are shown as extending in the first direction DR1 as an example. Hereinafter, for simplicity, the following describes an example in which the transmission area OA and the non-transmission area LSA include separated, stripe-shaped regions that extend in the first direction DR1.

The emission area EA of the display area DA may overlap the transmission area OA and the non-transmission area LSA. For example, the first to third emission areas EA1, EA2, and EA3 may overlap the transmission area OA and the non-transmission area LSA.

The transmission area OA may be an area in which the light blocking film LS of the light control layer LCL is not disposed. The non-transmission area LSA may be an area in which the light blocking film LS of the light control layer LCL is disposed. The light transmitting film LT may be disposed in the transmission area OA.

In some embodiments, the transmission area OA and the non-transmission area LSA may include stripes that extend along the first direction DR1. The stripes of the transmission area OA and the non-transmission area LSA may be alternately disposed in the second direction DR2.

As shown in FIG. 8, the light control layer LCL may be disposed on the touch sensor layer TSU, which is described above with reference to FIG. 5. The light control layer LCL may control a viewing angle of light emitted from the light emitting layer 172. For example, when the light emitted from the light emitting layer 172 travels at a predetermined angle or less with respect to the third direction DR3, the light may pass through the light control layer LCL be emitted from the display panel 100. On the other hand, when the light emitted from the light emitting layer 172 propagates at an angle greater than a predetermined angle with respect to the third direction DR3, that light may be absorbed or blocked by the light blocking film LS and may not be emitted from the display panel 100.

The light control layer LCL may include the light blocking film LS and the light transmitting film LT.

The light blocking film LS may be disposed on the touch sensor layer TSU. The light blocking film LS may be disposed in the non-transmission area LSA. In one embodiment, as shown in FIG. 7, the light blocking film LS may include stripe-shaped regions that are disposed alternately with stripe-shaped regions of the light transmitting film LT. In alternative embodiments, the stripe-shaped regions may extend in the first direction DR1 or the second direction DR2. In another embodiment, the light blocking film LS may include a plurality of openings disposed in the transmission area OA, as shown in FIG. 1. In this case, the light blocking film LS may surround areas of the light transmitting film LT.

The light blocking film LS may absorb or block the light emitted from the light emitting layer 172. The light blocking film LS may include a light blocking organic material. For example, the light blocking film LS may be a photosensitive resin capable of absorbing or blocking light and may include an organic material containing an organic black pigment such as carbon black.

The light transmitting film LT may be disposed on the touch sensor layer TSU. The light transmitting film LT may be disposed in the transmission area OA. In one embodiment, as shown in FIG. 7, the light transmitting film LT may include stripe-shaped regions that are alternately disposed with stripe-shaped regions of the light blocking film LS. Again, the striped-shaped regions may extend in the first direction DR1 or the second direction DR2. In another embodiment, as shown in FIG. 1, the light transmitting film LT may be disposed in the openings in the light blocking film LS and may be surrounded by the light blocking film LS.

The light transmitting film LT may transmit the light emitted from the light emitting layer 172. The light transmitting film LT may include a transparent organic material. For example, the light transmitting film LT may include an organic layer such as acryl resin, epoxy resin, phenolic resin, polyamide resin, polyimide resin and the like. In another embodiment, the light transmitting film LT may include silicon oxynitride or silicon oxide.

In some embodiments, a width LT_W of each striped-shaped region of the light transmitting film LT may be greater than a width LS_W of each stripe-shaped region of the light blocking film LS. For example, the width LT_W may be 2 to 5 times the width LS_W. In one example, the width LS_W may be approximately 2 μm to 10 μm but is not limited thereto.

In the display device 10 according to the present embodiment, the light control layer LCL may include the inspection pattern ISP. The inspection pattern ISP may be disposed and patterned to facilitate inspection of the etching amount and etching shape of the light transmitting film LT or the light blocking film LS. An embodiment of the display device inspection method S1 (see FIG. 13) is described below.

The inspection pattern ISP may include the same material as the light transmitting film LT. The inspection pattern ISP may extend in the first direction DR1. The inspection pattern ISP may overlap the non-transmission area LSA and may correspond to a portion removed from a stripe of the light blocking material that extends in the first direction DR1 in FIG. 7. The inspection pattern ISP may be disposed between remaining portions of the stripe of the light blocking film LS, which extend in the first direction DR1.

In some embodiments, the inspection pattern ISP may be disposed in the display area DA. In the display device 10 according to the present embodiment, by placing the inspection pattern ISP in the display area DA, the inspection accuracy may be improved compared to a case where the inspection pattern exists on a test element group (TEG) region disposed in the non-display area NDA. The TEG region may be a test region separately provided for the purpose of checking whether the light emitting element 170 disposed in the display area DA is driven.

The inspection pattern ISP may not overlap the emission area EA. For example, the inspection pattern ISP may be disposed between the third emission areas EA3 in a column extending in the second direction DR2. For example, the inspection pattern ISP may be disposed in a space formed between the third emission area EA3 included in the pixel PX disposed in the first row R1 and the third emission area EA3 included in the pixel PX disposed in the second row R2. The inspection pattern ISP may be disposed between (in the first direction DR1) the first emission areas EA1 and/or between the second emission areas EA2 in adjacent columns.

The present disclosure is not limited to the specific embodiment of the inspection pattern ISP shown in FIG. 7, and the inspection pattern ISP may be disposed between the first emission area EA1 and the second emission area EA2 in the second direction DR2, between the first emission area EA1 and the third emission area EA3 in the first direction DR1, or between the second emission area EA2 and the third emission area EA3 in the first direction DR1. That is, the inspection pattern ISP may be disposed at various positions in an area that does not overlap the emission area EA.

In the display device 10 according to the present embodiment, by placing the inspection pattern ISP so as not to overlap the emission area EA, it is possible to prevent the viewing angle control characteristic of the light control layer LCL from being degraded.

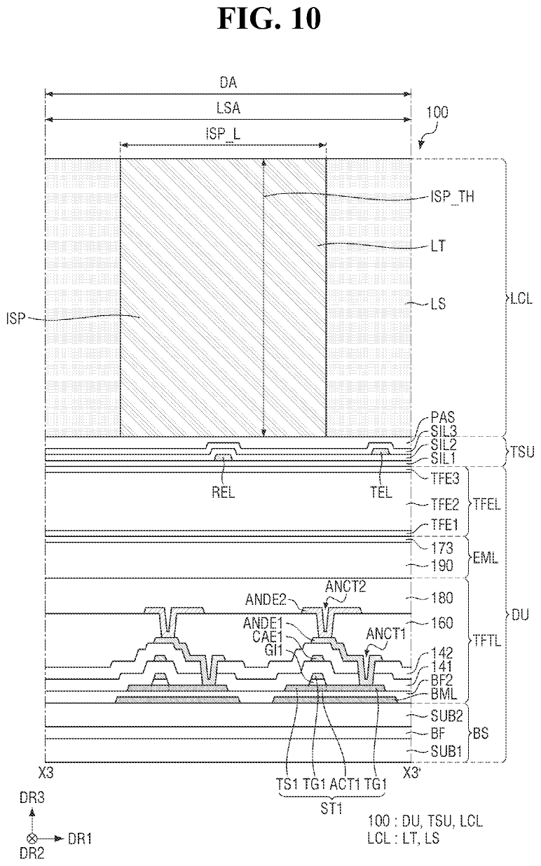

FIG. 9 is an enlarged view of area A of FIG. 7. FIG. 10 is a cross-sectional view taken along line X3-X3′ of FIG. 9.

Referring to FIGS. 9 and 10 in addition to FIGS. 1 to 3 and 7, the inspection pattern ISP may include the same material as the light transmitting film LT. The inspection pattern ISP may be a single component physically coupled with the light transmitting films LT adjacent to opposite sides of the inspection pattern ISP in the second direction DR2. For example, the light transmitting films LT adjacent to opposite sides of the inspection pattern ISP may be connected to each other through the inspection pattern ISP.

The light blocking films LS may be disposed on opposite sides of the inspection pattern ISP in the first direction DR1. The inspection pattern ISP may overlap, in the first direction DR1, the light blocking film LS, which extends in the first direction DR1.

In some embodiments, a width ISP_W of the inspection pattern ISP in the second direction DR2 may be the same as the width LS_W of the light blocking film LS in the second direction DR2. For example, the width ISP_W of the inspection pattern ISP may be approximately 2 μm to 10 μm but is not limited thereto.

In some embodiments, a thickness ISP_TH of the inspection pattern ISP may be the same as a thickness LS_TH of the light blocking film LS and a thickness LT_TH of the light transmitting film LT. For example, the thickness ISP_TH of the inspection pattern ISP may be approximately 20 μm to 50 μm but is not limited thereto.

In the display device 10 according to the present embodiment, a length ISP_L of the inspection pattern ISP in the first direction DR1 may be greater than the width ISP_W of the inspection pattern ISP in the second direction DR2. For example, the length ISP_L of the inspection pattern ISP in the first direction DR1 may be approximately 5 μm to 20 μm but is not limited thereto.

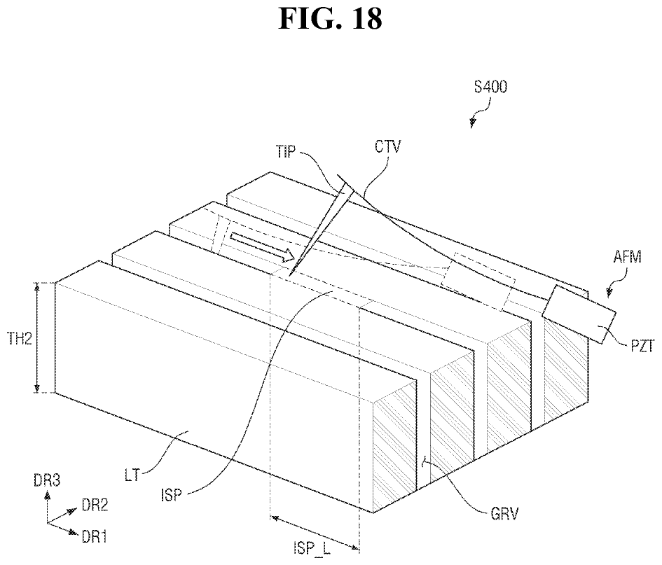

In the display device 10 according to the present embodiment, since the length ISP_L of the inspection pattern ISP in the first direction DR1 is greater than the width ISP_W of the inspection pattern ISP in the second direction DR2, when inspecting the etching amount and etching shape of the light transmitting film LT according to the display device inspection method S1 (see FIG. 13) described below, damage to a tip TIP (see FIG. 18) of an inspection device AFM (see FIG. 18) may be prevented. This will be described below with reference to FIG. 13.

Hereinafter, other embodiments of the display device are described. In the following embodiments, description of the components that are the same as those of the above-described and denoted by like reference numerals, may be omitted or simplified, and differences are mainly described.

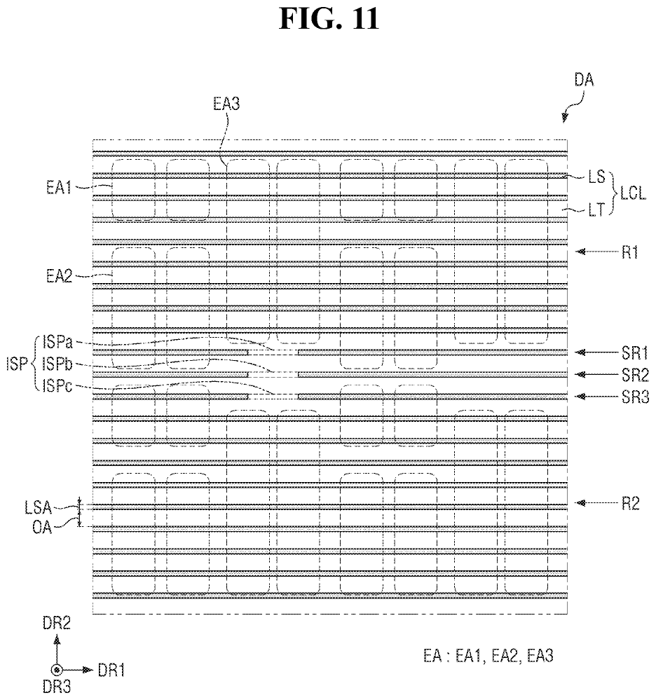

FIG. 11 is a plan view illustrating a part of a light control layer and a display area including an emission area in a display device according to another embodiment.

Referring to FIG. 11, the display device 10 according to the present embodiment differs from the display device 10 according to one embodiment described with reference to FIG. 7 and the like in that the inspection pattern ISP of FIG. 11 includes first to third sub-inspection patterns ISPa, ISPb, and ISPc.

In the embodiment of FIG. 11, a space formed between the third emission area EA3 included in the pixel PX disposed in the first row R1 and the third emission area EA3 included in the pixel PX disposed in the second row R2 may overlap, in the third direction DR3, a plurality of the regions of the non-transmission area LSA. For example, as shown in the drawing, the above-described space may overlap, in the third direction DR3, three regions of the non-transmission area LSA respectively disposed in first to third sub-rows SR1, SR2, and SR3.

The inspection pattern ISP may include the first sub-inspection pattern ISPa, the second sub-inspection pattern ISPb, and the third sub-inspection pattern ISPc. The first to third sub-inspection patterns ISPa, ISPb, and ISPc may be disposed to overlap the above-described space in the third direction DR3. For example, the first sub-inspection pattern ISPa may be disposed in the first sub-row SR1, the second sub-inspection pattern ISPb may be disposed in the second sub-row SR2, and the third sub-inspection pattern ISPc may be disposed in the third sub-row SR3.

The first to third sub-inspection patterns ISPa, ISPb, and ISPc may be arranged side by side along the second direction DR2. Each of the first to third sub-inspection patterns ISPa, ISPb, and ISPc may extend in the first direction DR1 and may have the same length in the first direction DR1.

Each of the first to third sub-inspection patterns ISPa, ISPb, and ISPc may be disposed between segments of the light blocking film LS, which extend in the first direction DR1. For example, the first sub-inspection pattern ISPa may be disposed between segments of the light blocking film LS disposed in the first sub-row SR1, the second sub-inspection pattern ISPb may be disposed between segments of the light blocking film LS disposed in the second sub-row SR2, and the third sub-inspection pattern ISPc may be disposed between segments of the light blocking film LS disposed in the third sub-row SR3.

In the display device 10 according to the embodiment of FIG. 11, since the inspection pattern ISP includes the plurality of sub-inspection patterns ISPa, ISPb, and ISPc, the inspection accuracy of the display device inspection method S1 (see FIG. 13) described below may be improved.

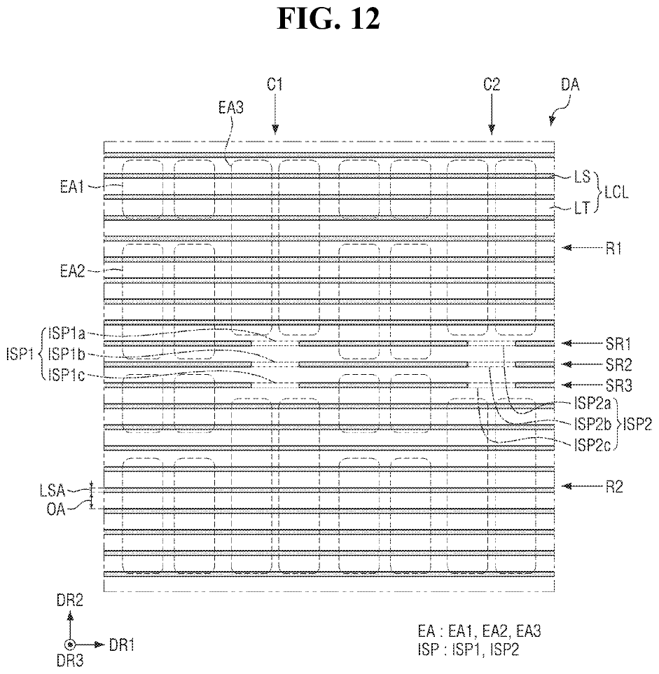

FIG. 12 is a plan view illustrating a part of a light control layer and a display area including an emission area in a display device according to another embodiment.

Referring to FIG. 12, the display device 10 according to the embodiment of FIG. 12 differs from the display device 10 according to the embodiment described with reference to FIG. 11 and the like in that the embodiment of FIG. 12 includes a plurality of inspection patterns ISP.

More specifically, a space formed between the third emission area EA3 included in the pixel PX disposed in the first row R1 and the third emission area EA3 included in the pixel PX disposed in the second row R2 may overlap the plurality of non-transmission areas LSA in the third direction DR3. For example, as shown in the drawing, the above-described space may overlap, in the third direction DR3, three regions of the non-transmission area LSA respectively disposed in the first to third sub-rows SR1, SR2, and SR3. The above space may include a first space disposed in a first column C1 and a second space disposed in a second column C2.

The plurality of inspection patterns ISP may include a first inspection pattern ISP1 and a second inspection pattern ISP2. The first inspection pattern ISP1 may be disposed in the first column C1, and the second inspection pattern ISP2 may be disposed in the second column C2.

The first inspection pattern ISP1 may include a first sub-inspection pattern ISP1a, a second sub-inspection pattern ISP1b, and a third sub-inspection pattern ISP1c. The first to third sub-inspection patterns ISP1a, ISP1b, and ISP1c may be disposed to overlap the first space in the third direction DR3. For example, the first sub-inspection pattern ISP1a may be disposed in the first sub-row SR1 in the first column C1, the second sub-inspection pattern ISP1b may be disposed in the second sub-row SR2 in the first column C1, and the third sub-inspection pattern ISP1c may be disposed in the third sub-row SR3 in the first column C1.

The second inspection pattern ISP2 may include a fourth sub-inspection pattern ISP2a, a fifth sub-inspection pattern ISP2b, and a sixth sub-inspection pattern ISP2c. The fourth to sixth sub-inspection patterns ISP2a, ISP2b, and ISP2c may be disposed to overlap the second space in the third direction DR3. For example, the fourth sub-inspection pattern ISP2a may be disposed in the first sub-row SR1 in the second column C2, the fifth sub-inspection pattern ISP2b may be disposed in the second sub-row SR2 in the second column C2, and the sixth sub-inspection pattern ISP2c may be disposed in the third sub-row SR3 in the second column C2.

The first to third sub-inspection patterns ISP1a, ISP1b, and ISP1c may be arranged side by side along the second direction DR2 in the first column C1. Each of the first to third sub-inspection patterns ISP1a, ISP1b, and ISP1c may extend in the first direction DR1 and may have the same length in the first direction DR1.

The fourth to sixth sub-inspection patterns ISP2a, ISP2b, and ISP2c may be arranged side by side along the second direction DR2 in the second column C2. Each of the fourth to sixth sub-inspection patterns ISP2a, ISP2b, and ISP2c may extend in the first direction DR1 and may have the same length in the first direction DR1.

Each of the first to third sub-inspection patterns ISP1a, ISP1b, and ISP1c may be disposed between segments of the light blocking film LS, which extend in the first direction DR1. For example, the first sub-inspection pattern ISP1a may be disposed between segments of the light blocking film LS disposed in the first sub-row SR1, the second sub-inspection pattern ISP1b may be disposed between segments of the light blocking film LS disposed in the second sub-row SR2, and the third sub-inspection pattern ISP1c may be disposed between segments of the light blocking film LS disposed in the third sub-row SR3.

Each of the fourth to sixth sub-inspection patterns ISP2a, ISP2b, and ISP2c may be disposed between segments of the light blocking film LS, which extend in the first direction DR1. For example, the fourth sub-inspection pattern ISP2a may be disposed between segments of the light blocking film LS disposed in the first sub-row SR1, the fifth sub-inspection pattern ISP2b may be disposed between segments of the light blocking film LS disposed in the second sub-row SR2, and the sixth sub-inspection pattern ISP2c may be disposed between segments of the light blocking film LS disposed in the third sub-row SR3.

The first sub-inspection pattern ISP1a and the fourth sub-inspection pattern ISP2a may be positioned opposite each other with a segment of the light blocking film LS interposed therebetween. The second sub-inspection pattern ISP1b and the fifth sub-inspection pattern ISP2b may be positioned opposite each other with a segment of the light blocking film LS interposed therebetween. The third sub-inspection pattern ISP1c and the sixth sub-inspection pattern ISP2c may be positioned opposite each other with a segment of the light blocking film LS interposed therebetween.

In the display device 10 according to the embodiment of FIG. 12, since the plurality of inspection patterns ISP are included, the inspection accuracy of the display device inspection method S1 (see FIG. 13) described below may be improved.

Hereinafter, a method of manufacturing a display device according to one embodiment will be described.

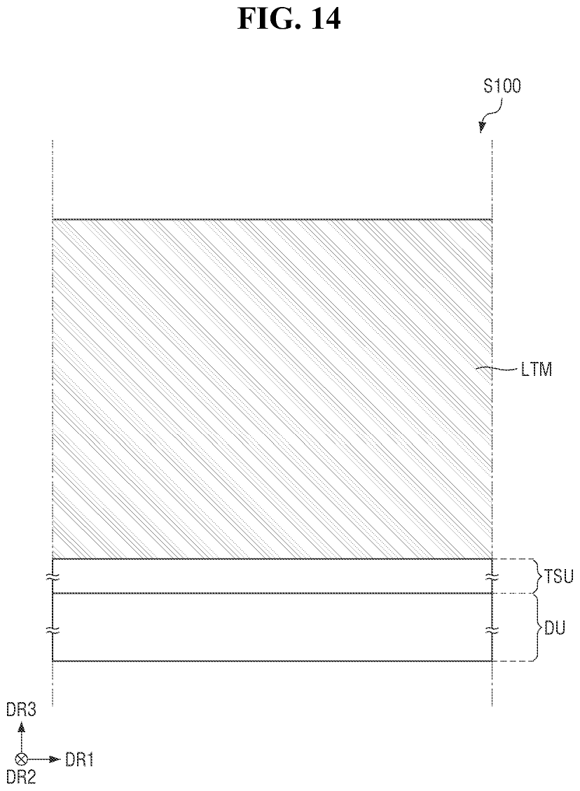

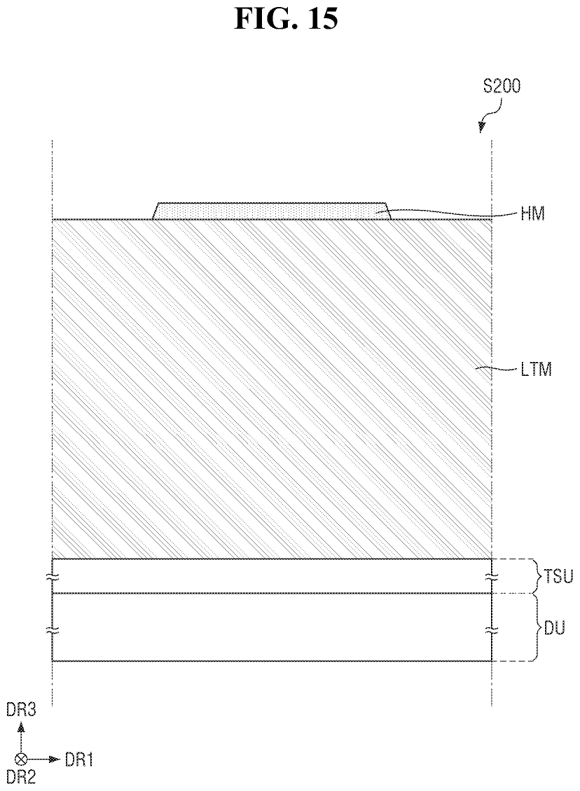

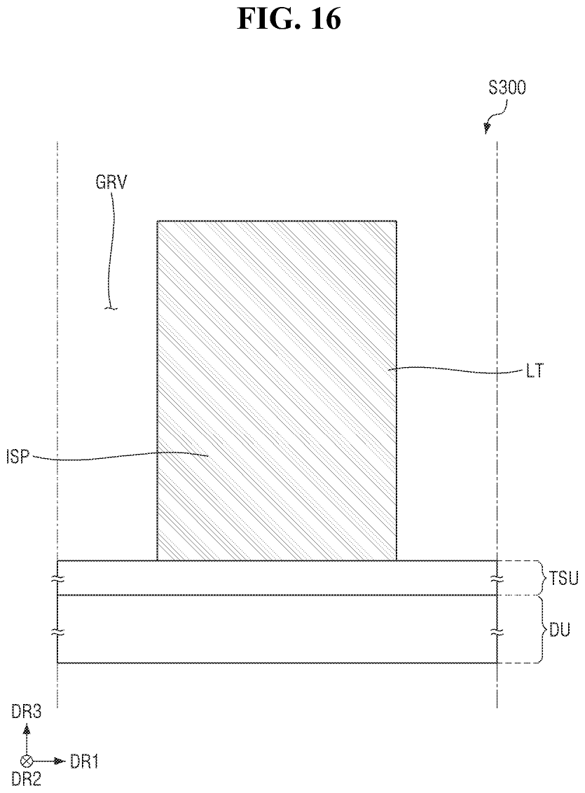

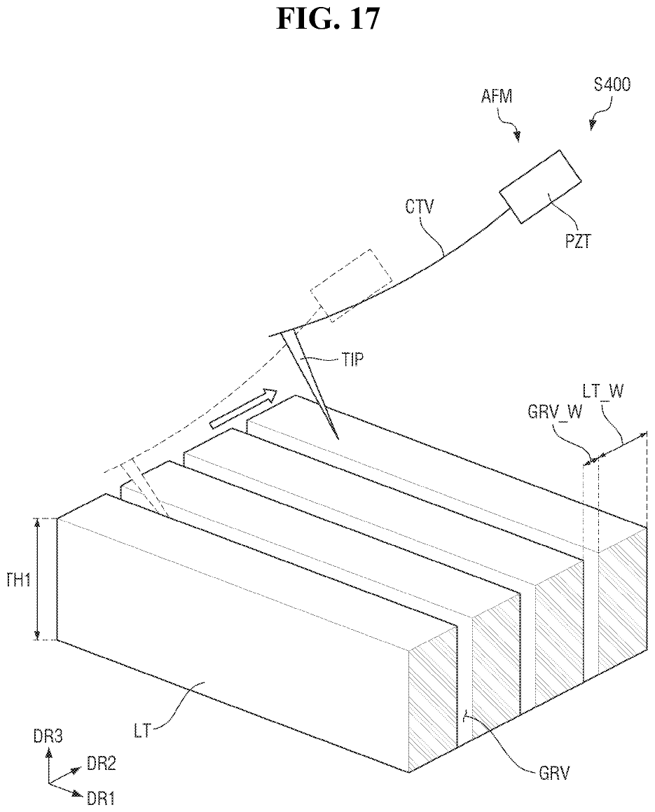

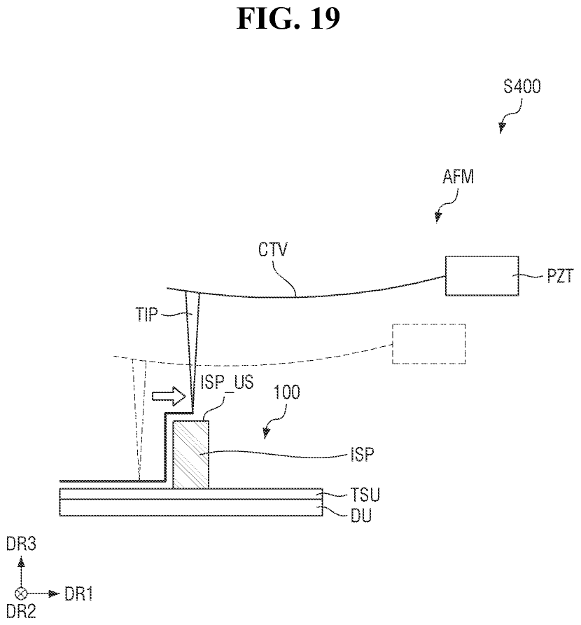

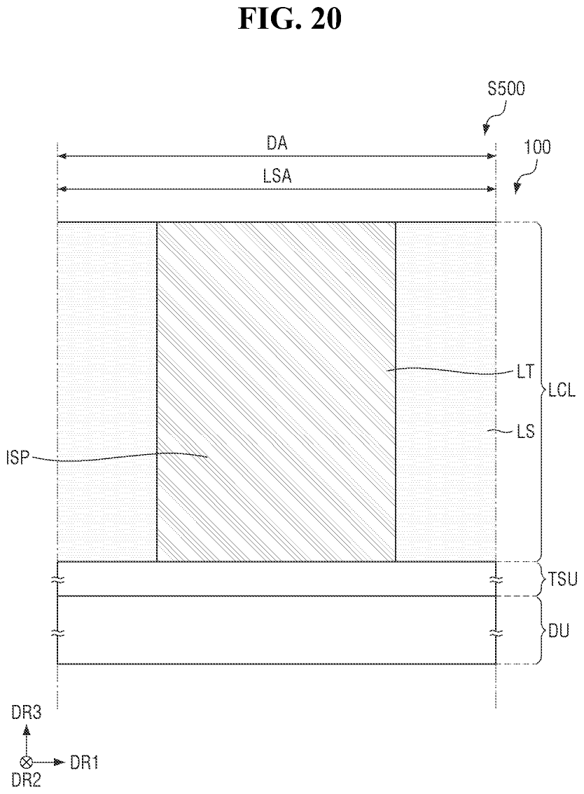

FIG. 13 is a flowchart illustrating a method for inspecting a display device according to one embodiment. FIG. 14 is a cross-sectional view showing a structure resulting from a step S100 of FIG. 13. FIG. 15 is a cross-sectional view showing a structure resulting from a step S200 of FIG. 13. FIG. 16 is a cross-sectional view showing a structure resulting from a step S300 of FIG. 13. FIG. 17 is a perspective view showing a structure resulting from a step S400′ according to a comparative embodiment. FIG. 18 is a perspective view showing a structure resulting from a step S400 of FIG. 13. FIG. 19 is a cross-sectional view showing a structure resulting from a step S400 of FIG. 13. FIG. 20 is a cross-sectional view showing a structure resulting from a step S500 of FIG. 13.

Referring to FIGS. 13 to 20, the display device inspection method S1 according to one embodiment may include forming a light transmitting material layer on the touch sensor layer (step S100), forming a hard mask on the light transmitting material layer (step S200), forming the light transmitting film (step S300), inspecting the etching amount and etching shape of the light transmitting film (step S400), and forming the light blocking film (step S500).

Firstly, step S100 may form a light transmitting material layer LTM on the touch sensor layer TSU of the display panel 100, The display panel 100 may particularly include the display layer DU and the touch sensor layer TSU, which may be prepared as described above with reference to FIG. 5. In one embodiment, the light transmitting material layer LTM may include an organic layer such as acryl resin, epoxy resin, phenolic resin, polyamide resin, polyimide resin and the like. In another embodiment, the light transmitting film LT may include silicon oxynitride or silicon oxide.

Secondly, step S200 may form a hard mask HM on the light transmitting material layer LTM. For example, a deposition process and a patterning process may form the hard mask HM. More particularly, a material contained in the hard mask HM may be deposited on the entire surface of the light transmitting material layer LTM. The material contained in the hard mask HM may include at least one of aluminum, chromium, copper, nickel, or oxide thereof, but is not limited thereto. The material contained in the hard mask HM may be deposited through a sputtering process or another physical vapor deposition (PVD) method. However, the present disclosure is not limited thereto, and the material may be deposited through a chemical vapor deposition (CVD) method, an atomic layer deposition (ALD) method, or the like. The hard mask material layer may be disposed on the entire surface of the light transmitting material layer LTM and may be patterned to form the hard mask HM. For example, the hard mask HM may be patterned through a photolithography process.

Thirdly, step S300 forms the light transmitting film LT. In particular, the light transmitting material layer LTM may be patterned using the hard mask HM to form the inspection pattern ISP and the light transmitting film LT. For example, an etch process may remove a part of the light transmitting material layer LTM that does not overlap the hard mask HM. The part of the light transmitting material layer LTM that does not overlap the hard mask HM may be etched through dry etching but is not limited thereto.

A groove or a plurality of grooves GRV may be formed in a portion where the light transmitting material layer LTM is etched, so that the light transmitting film LT may be formed. In one embodiment, the grooves GRV and the light transmitting film LT may include stripes that extend along the first direction DR1 as shown in FIG. 18.

Etching of the light transmitting material layer LTM may also form the inspection pattern ISP between regions of the light transmitting films LT extending in the first direction DR1. As shown in FIGS. 16 and 18, the inspection pattern ISP may be disposed between the grooves GRV, which extend in the first direction DR1. As shown in FIG. 18, the inspection pattern ISP may be disposed between striped-shaped regions of the light transmitting film LT, which extend in the first direction DR1.

Fourthly, in step S400 of inspecting the etching amount and etching shape of the light transmitting film, the etching amount and etching shape of the light transmitting film LT may be inspected using the inspection device AFM. The inspection device AFM may be a type of scanning probe microscope such as an atomic force microscope. In the present embodiment, the inspection device AFM is illustrated as a non-contact atomic force microscope but is not limited thereto. For example, the inspection device AFM may be a contact or tapping atomic force microscope.

The inspection device AFM may include a scanner PZT, a cantilever CTV, and a tip TIP.

The scanner PZT may expand and contract such that a constant atomic force may act between a subject and the tip TIP. For example, the scanner PZT may include a piezoelectric tube.

The cantilever CTV may be a structure in which one end is fixed to the scanner PZT and the other end is freely movable. The cantilever CTV may have flexibility and may be bent depending on the movement of the tip TIP coupled to the free end of the cantilever CTV.

The tip TIP may move in the first to third directions DR1, DR2, and DR3 depending on the shape of the subject, e.g., the light transmitting film LT. The tip TIP may have a shape protruding from the cantilever CTV toward the subject. The tip TIP may be formed of the same material as the cantilever CTV and integrally formed with the cantilever CTV.

As shown in FIG. 17, according to the display device inspection method S1 according to a comparative embodiment, the inspection device AFM may scan the light transmitting film LT in the second direction DR2 rather than the first direction DR1, which is the extension direction of the groove GRV and the light transmitting film LT. In this case, a width GRV_W of the groove GRV is smaller than the width LT_W of the light transmitting film LT and a thickness TH1 of the light transmitting film LT, which may cause problems such as the tip TIP of the inspection device AFM being broken or damaged in a process of measuring the depth of the groove GRV. For example, when moving to the top surface of the light transmitting film LT after measuring the depth of the groove GRV, the tip TIP may be broken or damaged.

On the other hand, as shown in FIGS. 18 and 19, according to the display device inspection method S1 according to the present embodiment, the inspection device AFM may scan the light transmitting film LT in the first direction DR1, which is the extension direction of the groove GRV and the light transmitting film LT.

In this case, in the display device 10 according to the present embodiment, since the length ISP_L of the inspection pattern ISP disposed between the grooves GRV in the first direction DR1 may be sufficiently secured, damage to the tip TIP of the inspection device AFM may be minimized. For example, when moving toward a top surface ISP_US of the inspection pattern ISP after measuring the depth of the groove GRV, damage to the tip TIP may be minimized.

Fifthly, in step S500 of forming the light blocking film, when there is no abnormality in the etching amount and etching shape of the light transmitting film LT, the light blocking film LS may be formed in the groove GRV.

For example, a material included in the light blocking film LS may be disposed between regions of the light transmitting films LT, i.e., in the groove GRV. For example, the material included in the light blocking film LS may be a photosensitive resin capable of absorbing or blocking light and may include an organic material containing an organic black pigment such as carbon black.

The light blocking film LS may be formed in the groove GRV, and accordingly, the light control layer LCL including the light transmitting film LT and the light blocking film LS may be formed.

According to the display device inspection method S1 according to the present embodiment, in a process of forming the light control layer LCL of the display device 10, after etching the light transmitting film LT, the inspection pattern ISP may be directly inspected to inspect the etching amount and etching shape of the light transmitting film LT. Accordingly, reliability of the light control layer LCL may be improved.

In concluding the detailed description, those skilled in the art will appreciate that many variations and modifications can be made to the preferred embodiments without departing from the principles of the present disclosure. Therefore, the disclosed preferred embodiments are used in a generic and descriptive sense only and not for purposes of limitation.

What is claimed is:

1. A display device comprising:
a substrate;
a light emitting element layer disposed on the substrate, and comprising a plurality of light emitting elements; and
a light control layer disposed on the light emitting element layer, and comprising a light transmitting film and a light blocking film, wherein
the light control layer further comprises an inspection pattern that overlaps the light blocking film in a first direction, and
the inspection pattern extends in the first direction which is the same direction as an extension direction of regions of the light blocking film.

2. The display device of claim 1, wherein the inspection pattern is disposed between at least two of the regions of the light blocking film, the at least two regions being aligned along the first direction.

3. The display device of claim 1, wherein regions of the light transmitting film and the regions of the light blocking film are disposed alternately in a second direction different from the first direction.

4. The display device of claim 3, wherein the inspection pattern is disposed between regions of the light transmitting films that are adjacent in the second direction.

5. The display device of claim 4, wherein
the regions of the light transmitting film disposed on opposite sides of the inspection pattern are connected to each other by the inspection pattern, and
the regions of the light transmitting films disposed on the opposite sides of the inspection pattern are physically coupled with the inspection pattern to form a single component.

6. The display device of claim 1, wherein the inspection pattern contains the same material as the light transmitting film.

7. The display device of claim 1, wherein in a second direction different from the first direction, a width of the inspection pattern is equal to a width of each of the regions of the light blocking film.

8. The display device of claim 1, wherein a length of the inspection pattern in the first direction is greater than a width of the inspection pattern in a second direction different from the first direction.

9. The display device of claim 1, wherein a thickness of the inspection pattern is equal to a thickness of the light transmitting film.

10. The display device of claim 1, wherein the substrate comprises a display area where the plurality of light emitting elements are disposed, and a non-display area disposed on at least one side of the display area, and
the inspection pattern is disposed in the display area.

11. The display device of claim 10, wherein the display area comprises an emission area configured to emit the light, and
the inspection pattern does not overlap the emission area.

12. The display device of claim 1, wherein the regions of the light blocking film comprises a plurality of regions that are separate from each other in a second direction different from the first direction,
the inspection pattern comprises a plurality of sub-inspection patterns, and
the plurality of sub-inspection patterns each overlap, in the first direction, the plurality of regions of the light blocking film.

13. The display device of claim 12, further comprising a plurality of pixels in which the plurality of light emitting elements are respectively disposed,
the inspection pattern comprises a first inspection pattern and a second inspection pattern, and
the first inspection pattern and the second inspection pattern are disposed between the pixels adjacent to each other.

14. The display device of claim 1, wherein in a second direction different from the first direction, a width of regions of the light transmitting film is greater than a width of the regions of the light blocking film.

15. A display device comprising:
a substrate;
a light emitting element layer disposed on the substrate, and comprising a plurality of light emitting elements; and
a light control layer disposed on the light emitting element layer, and comprising a first light transmitting film region, a light blocking film region, and a second light transmitting film region, the first light transmitting film region, the light blocking film region, and the second light transmitting film region disposed alternately in a first direction, wherein
the light control layer further comprises an inspection pattern disposed between the first light transmitting film region and the second light transmitting film region in the first direction,
the light blocking film region comprises a first light blocking film segment and a second light blocking film segment that are adjacent in a second direction different from the first direction, and
the inspection pattern is disposed between the first light blocking film segment and the second light blocking film segment in the second direction.

16. The display device of claim 15, wherein the first light blocking film segment, the second light blocking film segment, and the inspection pattern extend in the second direction.

17. The display device of claim 15, wherein a thickness of the inspection pattern is equal to a thickness of the light blocking film region.

18. A method for inspecting a display device comprising a substrate, a light emitting element layer disposed on the substrate and comprising a plurality of light emitting elements, a light transmitting film including a plurality of light transmitting film regions disposed on the light emitting element layer, and an inspection pattern disposed between the regions of the light transmitting film, the method comprising:
inspecting the light transmitting film using an atomic force microscope having a tip, wherein
the inspection pattern extends in a first direction which is the same direction as an extension direction of the regions of the light transmitting film, and
in the inspecting of the light transmitting film, the tip moves in the first direction.

19. The method of claim 18, wherein a length of the inspection pattern in the first direction is greater than a width of the inspection pattern in a second direction different from the first direction.

20. The method of claim 18, further comprising a light blocking film between the regions of the light transmitting film.
